(19) United States
(12) Patent Application Publication
(10) Pub. No.: US 2015/0241317 A1
(43) Pub. Date: Aug. 27, 2015

(54) METHOD FOR MASS-PRODUCING COATED PRODUCTS

(71) Applicant: Panasonic Corporation, Osaka (JP)

(72) Inventor: TAKAYUKI MIYOSHI, Hyogo (JP)

(21) Appl. No.: 14/626,717

(22) Filed: Feb. 19, 2015

(30) Foreign Application Priority Data
Feb. 26, 2014 (JP) 2014-035302

(51) Int. Cl. G01M 99/00; B05B 12/08; B05D 1/02; B05B 1/02

(52) U.S. Cl. CPC G01M 99/008; B05B 1/02; B05B 12/082; B05D 1/02

(57) ABSTRACT

A method for mass-producing coated products includes: (a) selecting in which one or more nozzles are selected; (b) testing in which droplet landing accuracies of the respective selected one or more nozzles are tested by ejecting a droplet; (c) classifying in which each of the selected one or more nozzles is classified into one of a chronic defective condition level, a temporary defective condition level, and a good condition level in accordance with the obtained droplet landing accuracies; and (d) ejecting in which a droplet is ejected using nozzles determined to be in the good condition level. The selecting (a), testing (b), classifying (c), and ejecting (d) are repeatedly performed in this order. In the selecting (a), nozzles classified into the good condition level and at least one of nozzles classified into the temporary defective condition level in the classifying (c) of the preceding cycle are selected.

### CROSS REFERENCES TO RELATED APPLICATIONS

This application claims priority to Japanese Patent Application No. 2014-035302, filed on Feb. 26, 2014, the contents of which are hereby incorporated by reference.

### BACKGROUND

1. Technical Field

The present disclosure relates to a method for mass-producing coated products by ejecting droplets from a plurality of nozzles.

2. Description of the Related Art

For devices such as an organic EL device, a TFT substrate, and the like, a functional layer having a specific function is formed on a substrate. A functional layer is, for example, an organic light emitting layer in an organic EL device, an organic semiconductor layer on a TFT substrate, or the like.

The size of such a device has been recently increasing. As a method for efficiently forming a functional layer for such a device having a larger size, a wet method is used in which a solution containing a functional material (hereinafter referred to as “ink”) is applied to a substrate.

As a wet method, an ink-jet method is a representative example. In an ink-jet method, first, a substrate is arranged on a work table of a droplet ejection apparatus. A nozzle head is moved from side to side over a surface of the substrate, and ink droplets are ejected from a number of nozzles (for example, ten thousand nozzles) of the nozzle head. As a result, ink droplets are adhered to the surface of the substrate, and a functional layer is formed by drying the adhered droplets.

A technology for retaining high ejector performance in such an ink-jet method is disclosed, for example, in Japanese Unexamined Patent Application Publication No. 2008-209439. In Japanese Unexamined Patent Application Publication No. 2008-209439, the droplet landing accuracy of a droplet ejected from each nozzle of a droplet ejection apparatus is tested after performance of a maintenance operation. Then, normal nozzles specified in accordance with a result of the test are used on a priority basis.

### SUMMARY

One non-limiting and exemplary embodiment provides a method for mass-producing coated products by ejecting ink droplets from a plurality of nozzles toward a substrate, and the method for mass-producing coated products makes it possible to retain the droplet landing accuracy of ink droplets and also to reduce the frequency of a maintenance operation for nozzles.

Additional benefits and advantages of the disclosed embodiments will be apparent from the specification and Figures. The benefits and/or advantages may be individually provided by the various embodiments and features of the specification and drawings disclosure, and need not all be provided in order to obtain one or more of the same.

In one general aspect, the techniques disclosed here feature a method for mass-producing coated products having substrates. The method for mass-producing coated products includes: (a) selecting one or more nozzles from among the plurality of nozzles; (b) testing droplet landing accuracies of the one or more nozzles selected in the selecting (a) by causing a droplet to be ejected from the one or more nozzles; (c) classifying each of the one or more nozzles into one of a chronic defective condition level, a temporary defective condition level, and a good condition level in accordance with the droplet landing accuracies obtained in the testing (b); and (d) ejecting droplets toward at least one of the substrates with nozzles classified into the good condition level in the classifying (c), without using nozzles classified into the chronic defective condition level and the temporary defective condition level in the classifying (c) such that layers formed of the droplets are arranged on the substrates. The selecting (a), the testing (b), the classifying (c), and the ejecting (d) are repeatedly performed in this order as a cycle. In the selecting (a), nozzles classified into the good condition level in the classifying (c) of a preceding cycle and at least one of nozzles classified into the temporary defective condition level in the classifying (c) of the preceding cycle are selected.

Note that the general or specific aspect may also be realized using a device, a system, a method, or a computer program. In addition, the general or a specific aspect may also be realized by an arbitrary combination of devices, systems, methods, and computer programs.

### BRIEF DESCRIPTION OF THE DRAWINGS

FIG. 1 is a diagram illustrating a main configuration of a droplet ejection apparatus according to an embodiment;

FIG. 2 is a functional block diagram of the droplet ejection apparatus according to the embodiment;

FIG. 3 is a cross-sectional view of a nozzle head in the droplet ejection apparatus;

FIGS. 4A to 4D are a process diagram illustrating a method for manufacturing an organic EL device according to the embodiment;

FIG. 5 is a flowchart illustrating a process in which ink provided for a light emitting layer is applied to substrates and coated products are mass-produced, in the embodiment;

FIG. 6 is a diagram illustrating a method for performing a droplet landing test for nozzles in the droplet ejection apparatus;

FIG. 7 illustrates an example of a data table stored in a memory of a control device;

FIG. 8 is a flowchart illustrating a method in which the control device classifies each nozzle;

FIGS. 9A to 9E are graphs illustrating a specific example of a result of a droplet landing test performed for nozzles;

FIGS. 10A and 10B illustrate examples of a management table stored in the memory of the control device;

FIG. 11A is a diagram illustrating, in the case of line banks, a process in which ink provided for formation of a light emitting layer is applied to a substrate to be converted to a product; and

FIG. 11B is a diagram illustrating, in the case of a pixel bank, a process in which ink provided for formation of a light emitting layer is applied to a substrate to be converted to a product.

### DETAILED DESCRIPTION

### Underlying Knowledge Forming Basis of the Present Disclosure

In order to form a high-quality functional layer by an ink-jet method, the droplet landing accuracy of a droplet ejection apparatus needs to meet a certain level. That is, a deviation of a landing position of an ink droplet from a target position on a substrate, which is a coating target, needs to be small.

However, some nozzles may have an ejection orifice to which ink or dirt is adhered and may cause defective landing of droplets among a number of nozzles of a droplet ejection apparatus. Defective landing of droplets may cause defective coated products. For example, in the case where organic light emitting layers of organic EL devices are continuously formed using a nozzle that has caused defective landing of droplets, an ink droplet may land not on a target sub-pixel but on a sub-pixel adjacent to the target sub-pixel. This may be a cause of a mixture of colors of ink that forms a light emitting layer.

Thus, certain measures are taken in the case of mass-production such that the nozzles of a droplet ejection apparatus are periodically subjected to a maintenance operation and things that may clog the nozzles are removed.

A maintenance operation for nozzles is, for example, an operation for removing clogging compounds by strongly ejecting ink from each of the nozzles of a nozzle head, for wiping off ink adhered around the ejection orifice of each nozzle of the nozzle head, or the like.

In contrast, in the case of mass-production of an organic EL device or the like, it is desired to improve production efficiency in an ink application process using a droplet ejection apparatus. In order to improve production efficiency, it is desirable to reduce the frequency of a maintenance operation for nozzles as much as possible in the ink application process. That is, it is desirable to reduce as much as possible the rate of the number of times of a maintenance operation for the number of substrates to be coated.

In Japanese Unexamined Patent Application Publication No. 2008-209439, after performance of a maintenance operation, droplet landing deviations of droplets are measured for a plurality of nozzles of a droplet ejection apparatus. Then, the nozzles are classified into some levels from a defective level to a normal level in accordance with measurement results. Then, in the ink application process, a necessary number of nozzles are selected from the nozzles classified into the normal level on a priority basis and application of ink is performed.

In this manner, a droplet landing test is performed using ink for each nozzle, and only nozzles whose results of the droplet landing test are relatively good are selected and products are manufactured. As a result, the occurrence of defective landing of droplets may be reduced and non-defective products may be produced.

However, even though such a method is used, when the interval of maintenance operations is increased, even nozzles that have been classified into a good condition level may change to nozzles that are in a defective condition level while the nozzles are being used for manufacturing products. Thus, when the maintenance interval is too long, it becomes difficult to ensure the droplet landing accuracy of nozzles.

The inventor has come up with a mass-production method as in the following. That is, a droplet landing test is performed for nozzles in the interval of subsequent maintenance operations, and each nozzle is classified into a good condition level or a defective condition level. Then, ink is ejected to a certain number (N, for example, ten) of substrates to be converted to a product using only the nozzles classified into the good condition level. A series of processes of testing, classification, and ejection is repeatedly performed, and when a cumulative number of nozzles classified into the defective condition level reach the upper limit of a certain allowable range, a maintenance operation is performed for nozzles.

In the interval of subsequent maintenance operations, there may be the case where the condition of nozzles changes to the defective condition and defective landing of droplets occurs. However, according to a mass-production method of the present disclosure, a droplet landing test is performed every time ejection of ink to N substrates to be converted to a product is completed. A setting of “non-use” is set for nozzles the condition of which has changed to the defective condition in accordance with a result of this droplet landing test, and the nozzles are not used thereafter for manufacturing products. Thus, even when the maintenance interval is increased, the droplet landing accuracy of nozzles to be used may be ensured.

In order to further improve production efficiency, the inventor examined a method for extending the period before the cumulative number of nozzles classified into the defective condition level reaches the upper limit of a certain allowable range. As a result of examination, the inventor made new findings that the nozzles determined to be in the defective condition through the droplet landing test include nozzles that are in a chronic defective condition and nozzles that are in a temporary defective condition. That is, the inventor made findings that the nozzles that are in the temporary defective condition are likely to return to be in the good condition when subjected to a droplet landing test again.

In addition, the inventor found out that, in a droplet landing test, nozzles may be classified into nozzles that are in the chronic defective condition and nozzles that are in the temporary defective condition by extracting characteristics on positional deviations obtained by ejecting ink from each of the nozzles for a plurality of times on a substrate provided for a droplet landing test.

In accordance with these findings, use of nozzles that are in the temporary defective condition and that may return to be in the good condition is once stopped for manufacturing products. However, the nozzles are subjected to a droplet landing test again in the next cycle, and as a result, in the case where a nozzle among the nozzles is determined to be in the good condition, the nozzle is used again for manufacturing products.

In this manner, chances to be subjected to a droplet landing test again and to be used again for manufacturing products are given to the nozzles classified into the temporary defective condition level. As a result, an increase in the cumulative number of nozzles classified into the defective condition level may be reduced and the maintenance interval may be increased. That is, production efficiency may be improved by reducing the frequency of maintenance operations.

### Aspect of Present Disclosure

A method for mass-producing a coated product according to an aspect of the present disclosure is a method for mass-producing coated products having substrates, including: (a) selecting one or more nozzles from among the plurality of nozzles; (b) testing droplet landing accuracies of the one or more nozzles selected in the selecting (a) by causing a droplet to be ejected from the one or more nozzles; (c) classifying each of the one or more nozzles into one of a chronic defective condition level, a temporary defective condition level, and a good condition level in accordance with the droplet landing accuracies obtained in the testing (b); and (d) ejecting droplets toward at least one of the substrates with nozzles classified into the good condition level in the classifying (c), without using nozzles classified into the chronic defective condition level and the temporary defective condition level in the classifying (c), such that layers formed of the droplets are arranged on the substrates. The selecting (a), the testing (b), the classifying (c), and the ejecting (d) are repeatedly performed in this order as a cycle. In the selecting (a), nozzles classified into the good condition level in the classifying (c) of a preceding cycle and at least one of nozzles classified into the temporary defective condition level in the classifying (c) of the preceding cycle are selected.

According to the method of the above-described aspect, in the ejecting (d), application of ink is performed selectively using nozzles classified into the good condition level in accordance with a result of the testing (b). Thus, the droplet landing accuracy is ensured.

In addition, while the series of operations is being repeatedly performed, even when the condition of a nozzle classified into the good condition level changes to the defective condition during the ejecting (d), the nozzle is determined to be in the defective condition in the testing (b) of the next cycle and use of the nozzle is stopped. Thus, in the ejecting (d) of the next cycle, defective landing of droplets caused by nozzles that are in the defective condition may be prevented.

As a result, even though a maintenance operation is not frequently performed, the occurrence of defective landing of droplets may be reduced. That is, while the droplet landing accuracy of nozzles is retained, the interval of maintenance operations for the nozzles may be increased. Thus, the production efficiency may be improved.

In addition, according to the method of the above-described aspect, the droplet landing accuracy is tested in the testing (b) of the next cycle for at least some of the nozzles classified into the temporary defective condition level. The nozzles classified into the temporary defective condition level in the classifying (c) include nozzles that may return to be in a state in which the nozzles are usable again for manufacturing products. Thus, according to the method of the above-described aspect, nozzles the condition of which has changed to the good condition are selected from among the nozzles classified into the temporary defective condition level, and the selected nozzles may be used again for manufacturing products. That is, nozzles that may become usable again without performing a maintenance operation may be used efficiently.

Thus, the interval of maintenance operations for nozzles may be increased even more, and the production efficiency may be improved.

In addition, according to the method of the above-described aspect, the nozzles classified into the temporary defective condition level in a certain cycle are not used for manufacturing products in the cycle. Then, only in the case where it is determined through a droplet landing test that a nozzle is in the good condition, the nozzle is used again for manufacturing products. Thus, the droplet landing accuracy is ensured during manufacture of products.

In the method for mass-producing coated products according to the above-described aspect, in a case where a sum of a cumulative number of nozzles classified into the chronic defective condition level and a number of nozzles classified into the temporary defective condition level exceeds a certain value, a maintenance operation may be performed for at least one of the plurality of nozzles.

In this case, while the above-described series of operations is being repeatedly performed, a maintenance operation is not performed for nozzles. Then, when the sum of a cumulative number of nozzles classified into the chronic defective condition level and the number of nozzles classified into the temporary defective condition level exceeds a certain allowable range, a maintenance operation is performed.

In the method for mass-producing coated products according to the above-described aspect, in the testing (b), deviations of landing position where droplets actually land from target positions where droplets aim for may be measured about each of the one or more nozzles by causing a droplet to be ejected from each of the one or more nozzles a plurality of times. And in the classifying (c), each of the one or more nozzles may be classified into one of the chronic defective condition level, the temporary defective condition level, and the good condition level in accordance with the deviations.

In the method for mass-producing coated products according to the above-described aspect, in the classifying (c), a nozzle the deviations of which have a dispersion greater than a first reference value may be classified into one of the chronic defective condition level and the temporary defective condition level. And a nozzle the deviations of which have a dispersion less than or equal to the first reference value may be classified into the good condition level.

In the method for mass-producing coated products according to the above-described aspect, among nozzles classified into one of the chronic defective condition level and the temporary defective condition level in classifying (c), an ejection condition of a nozzle the deviations of which include two consecutive deviations greater than or equal to a second reference value may be classified into the chronic defective condition level. And a nozzle the deviations of which do not include two consecutive deviations greater than or equal to the second reference value may be classified into the temporary defective condition level.

In the method for mass-producing coated products according to the above-described aspect, among nozzles classified into the good condition level in the classifying (c), an ejection condition of a nozzle the deviations of which have an arithmetic mean value greater than a third reference value may be corrected before the ejecting (d).

In the method for mass-producing coated products according to the above-described aspect, in the classifying (c), a nozzle classified into the temporary defective condition level may be classified into one of a first temporary defective condition level and a second temporary defective condition level. A nozzle classified in the second temporary defective condition level may be less likely to be classified in the good condition level in a later cycle than a nozzle classified in the first temporary defective condition level. And in the selecting (a), a nozzle classified into the first temporary defective condition level in the classifying (c) of the preceding cycle and a nozzle classified into the good condition level in the classifying (c) of the preceding cycle may be selected.

### EMBODIMENTS

In the following, a method for mass-producing coated products according to an embodiment will be described with reference to the drawings.

Here, as an example, the case will be described where a functional layer in an organic EL device, especially a light emitting layer, is mass-produced using a droplet ejection apparatus by a wet method.

### First Embodiment

### Droplet Ejection Apparatus

First, a droplet ejection apparatus will be described.

### Overall Configuration of Droplet Ejection Apparatus

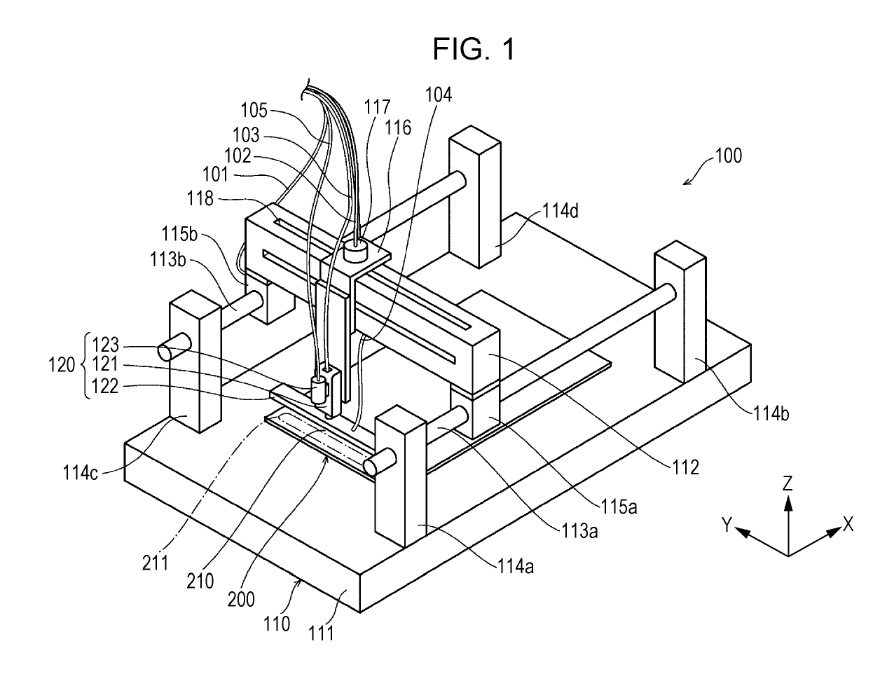

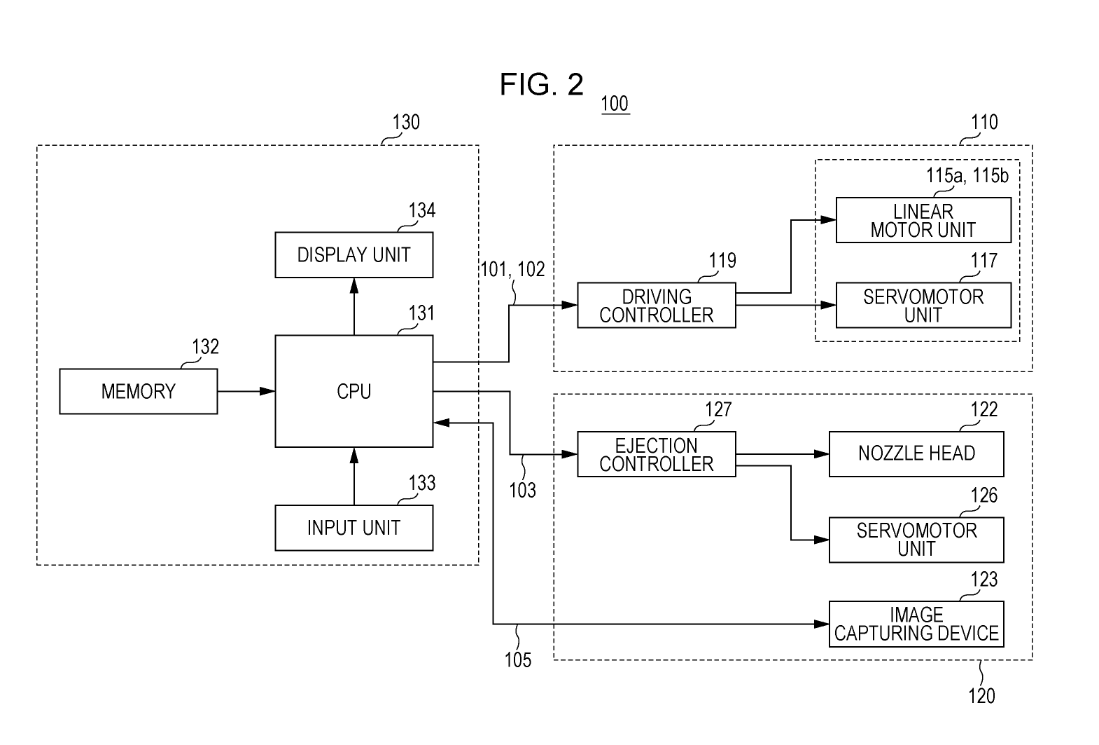

FIG. 1 is a diagram illustrating a main configuration of a droplet ejection apparatus according to a first embodiment. FIG. 2 is a functional block diagram illustrating this droplet ejection apparatus.

As illustrated in FIGS. 1 and 2, a droplet ejection apparatus 100 includes a work table 110, a head unit 120, and a control device 130.

### Work Table

The work table 110 is a so-called gantry work table. The work table 110 is provided with a base 111 where a coating target is placed and a movable rack 112 having a long length and arranged above the base 111.

In FIG. 1, a substrate 200 provided for a droplet landing test, is placed as a coating target.

The movable rack 112 spans between a pair of guide shafts 113a and 113b arranged parallel to the longitudinal direction of the base 111 (the X direction). The pair of guide shafts 113a and 113b are supported by columnar stands 114a to 114d provided at the four corners of the base 111.

The guide shafts 113a and 113b are provided with linear motor units 115a and 115b, respectively, and the linear motor units 115a and 115b make it possible to drive the movable rack 112 in the X direction.

The movable rack 112 is provided with an L-shaped base 116, and the L-shaped base 116 is provided with a servomotor unit 117. When the servomotor unit 117 is driven, the L-shaped base 116 and the head unit 120, with which the L-shaped base 116 is provided, are moved in the Y direction along a guide groove 118.

Thus, a nozzle head 122 and an image capturing device 123, with which the head unit 120 is provided, may be driven in the X direction and in the Y direction.

The linear motor units 115a and 115b and the servomotor unit 117 are connected to a driving controller 119 illustrated in FIG. 2. The driving controller 119 is connected to a central processing unit (CPU) 131 of the control device 130 via communication cables 101 and 102.

The CPU 131 sends a command to an ejection controller 127 in accordance with a control program stored in a memory 132 of the control device 130. In accordance with the command, the driving controller 119 performs driving control on the linear motor units 115a and 115b and the servomotor unit 117.

### Head Unit

The head unit 120 includes a main body portion 121, the nozzle head 122, and the image capturing device 123. The main body portion 121 is fixed to the L-shaped base 116. The nozzle head 122 and the image capturing device 123 are attached to the main body portion 121.

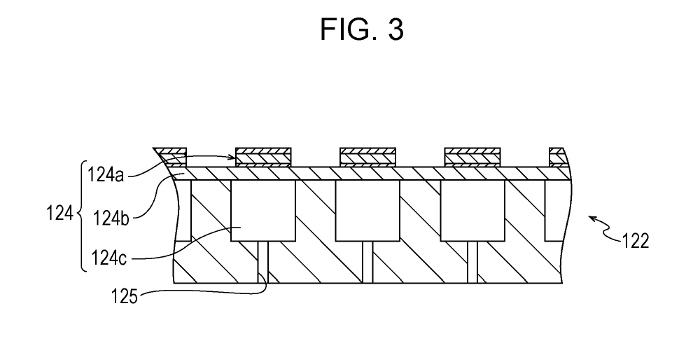

The nozzle head 122 is a columnar member extending in the Y direction. Although not illustrated in FIG. 1, a plurality of nozzles 125 (for example, on the order of ten thousands of nozzles 125) are arranged in a row in the Y direction on a bottom-surface side of the nozzle head 122 (see FIG. 3). Then, each nozzle 125 is provided with an ink ejection mechanism 124 including a piezoelectric element 124a, a diaphragm 124b, a liquid chamber 124c, and the like as constituent elements.

Then, ink is supplied into the liquid chamber 124c from the outside via a liquid injection tube 104 connected to the nozzle head 122.

When the volume of the liquid chamber 124c is reduced because of driving of the piezoelectric element 124a, the ink supplied to the liquid chamber 124c is ejected as droplets from the nozzles 125 to a coating target.

Note that, in the nozzle head 122, the arrangement of the plurality of nozzles 125 is not limited to one row. The plurality of nozzles 125 may also be arranged in a plurality of rows.

The main body portion 121 houses the ejection controller 127 provided with driving circuits that independently drive respective piezoelectric elements 124a. The ejection controller 127 causes a droplet to be ejected from the ejection orifice of each nozzle 125 by controlling a driving signal to be supplied to the piezoelectric element 124a corresponding to the nozzle 125. For example, for each piezoelectric element 124a, a driving voltage pulse to be applied to the piezoelectric element 124a is controlled by the ejection controller 127, and the volume, the timing of ejection, and the like of a droplet to be ejected from the corresponding nozzle 125 is adjusted.

The ejection controller 127 is connected to the CPU 131 of the control device 130 via a communication cable 103. The CPU 131 sends a command to the ejection controller 127 in accordance with a certain control program stored in the memory 132. The ejection controller 127 applies a driving voltage to a target piezoelectric element 124a in accordance with the command.

The image capturing device 123 is, for example, a CCD camera, and is connected to the control device 130 via a communication cable 105.

The image capturing device 123 captures an image of a surface of a coating target placed on the base 111. Image data of a captured image is transmitted to the control device 130. The CPU 131 stores the image data in the memory 132 and performs processing in accordance with a control program.

Note that a servomotor unit 126 is included in the main body portion 121. The servomotor unit 126 rotates the nozzle head 122 along an X-Y surface. Relative pitches of the nozzles 125 to a coating target may be adjusted by adjusting a rotation angle of the nozzle head 122.

### Control Device

The control device 130 includes the CPU 131, the memory 132 (including a mass storage such as an HDD), an input unit 133, and a display unit 134 (for example, a display). The control device 130 is specifically, for example, a personal computer (PC).

A control program for driving the work table 110 and the head unit 120 and the like is stored in the memory 132.

The CPU 131 performs control in accordance with a command input by an operator through the input unit 133 and various control programs stored in the memory 132.

The control device 130 causes the head unit 120 to undergo relative motion along the X-Y surface with respect to a coating target on the work table 110 in the droplet ejection apparatus 100.

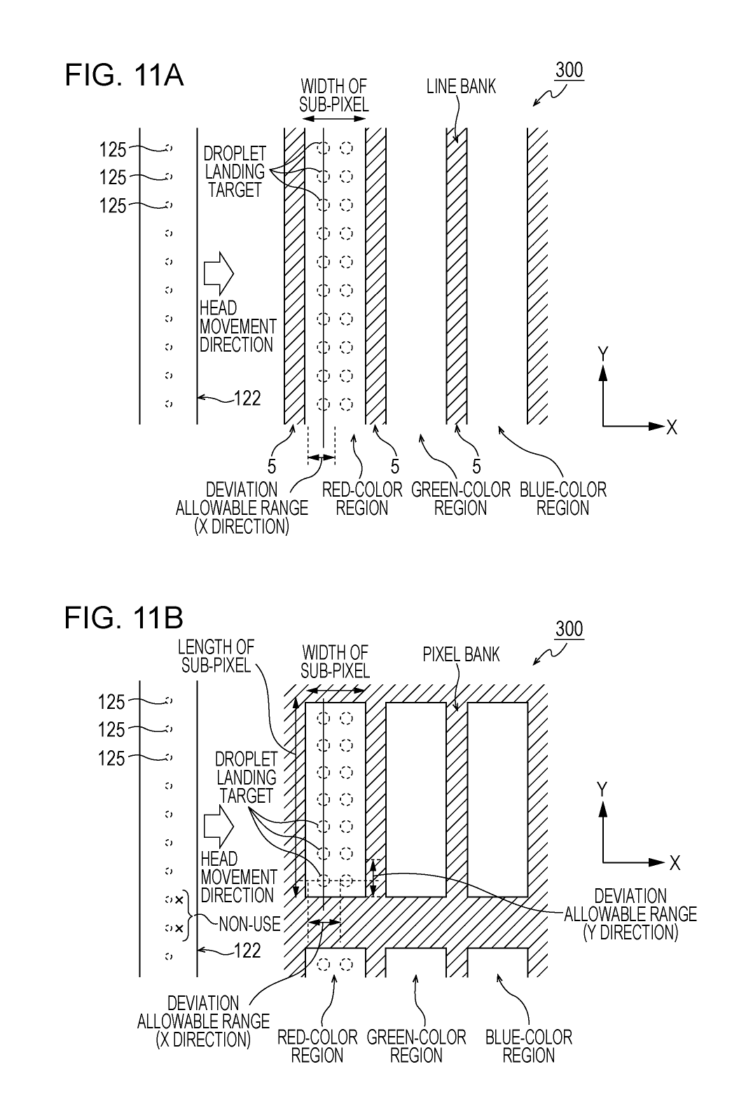

Although details will be described later, as illustrated in FIG. 11, the control device 130 causes ink to be ejected from the nozzles 125 at a certain timing to droplet landing targets on a substrate 300, which is a coating target, while moving the nozzle head 122 in the X direction. In addition, the control device 130 acquires image data of a surface of a substrate when a droplet landing test is performed.

In addition, for each of the plurality of nozzles 125 provided at the nozzle head 122, the control device 130 sets a setting of “use” (hereinafter referred to as “use”) or a setting of “non-use” (hereinafter referred to as “non-use”). Then, the control device 130 causes ink to be ejected only from nozzles 125 for which “use” has been set.

In addition, the control device 130 performs various types of processing for classifying nozzles 125, as described later, in accordance with a result of a droplet landing test.

### Overall Manufacturing Process of Organic EL Device

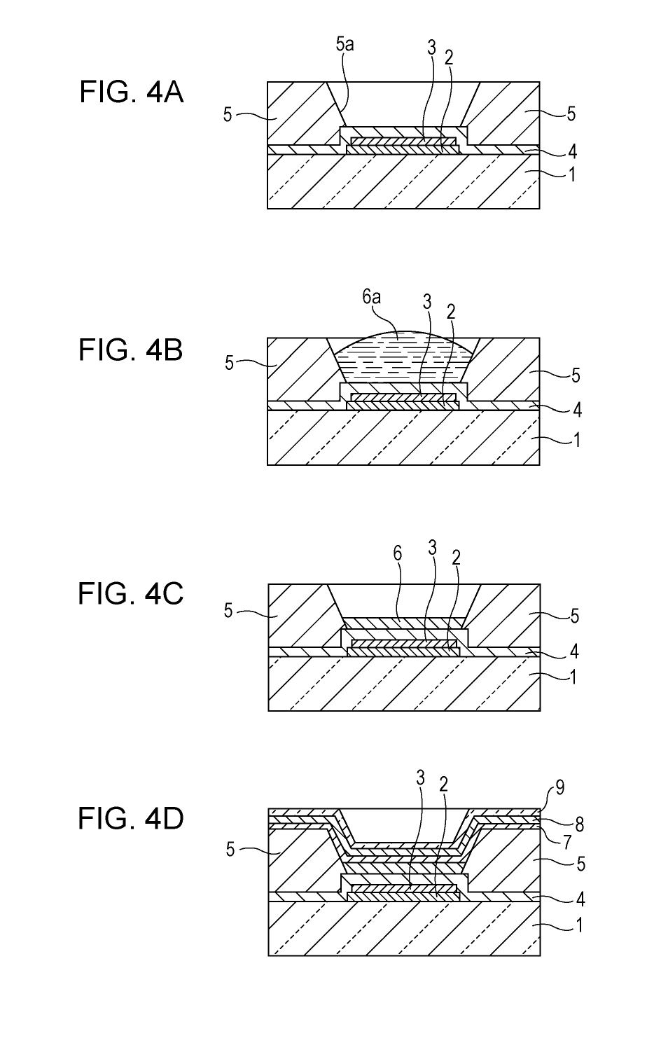

First, an overall process for manufacturing an organic EL device will be described. FIGS. 4A to 4D are a process diagram illustrating a method for manufacturing an organic EL device according to the first embodiment.

A substrate 1 may also be, for example, a TFT substrate on which a flattening film is formed by applying a photosensitive resin on the TFT substrate as well as exposing the applied photosensitive resin to light and performing development via a photomask.

As illustrated in FIG. 4A, an anode 2, an ITO layer 3, and a hole injection layer 4 are formed in this order on the substrate 1. Banks 5 are formed on the hole injection layer 4. As a result, a concave portion 5a, which is to be an element formation region, is formed between the banks 5.

The anode 2 may be formed by patterning an Ag thin film into a matrix form by photolithography method. The Ag thin film may be formed by, for example, sputtering or vacuum deposition.

The ITO layer 3 may be formed by patterning an ITO thin film by photolithography method. The ITO thin film may be formed by, for example, sputtering.

The hole injection layer 4 may be made of, for example, a composition including WOx or MoxWyOz. The composition may be formed by, for example, vacuum deposition or sputtering.

The banks 5 may be formed by forming a bank material layer through application of a bank material onto the hole injection layer 4 and by removing a portion of the bank material layer by etching. A surface of the banks 5 may also be subjected to, as needed, liquid repellent processing, for example, plasma processing using a fluoric material. In the first embodiment, the banks 5 are line banks. As illustrated in FIG. 11A, a plurality of line banks are formed parallel to each other on the substrate 1.

Next, as illustrated in FIG. 4B, light emitting layers of respective RGB colors are formed by a wet process in the concave portion 5a between the banks 5. Note that although FIGS. 4A to 4D illustrate one pair of banks 5, a plurality of banks 5 are arranged and formed in the lateral direction of the sheet of FIGS. 4A to 4D. Then, for each concave portion 5a between adjacent banks 5, any one of a red light emitting layer, a green light emitting layer, and a blue light emitting layer is formed. In this process, ink 6a containing a light emitting material of any one of a red light emitting layer, a green light emitting layer, and a blue light emitting layer is applied to the concave portion 5a between the banks 5. Then, as illustrated in FIG. 4C, a light emitting layer 6 is formed by drying the applied ink 6a under a reduced pressure.

Note that, although not illustrated in FIGS. 4A to 4D, a hole transport layer serving as a functional layer may also be formed by a wet process under the light emitting layer 6. In addition, an electron transport layer serving as a functional layer may also be formed by a wet process on the light emitting layer 6.

Next, as illustrated in FIG. 4D, an electron injection layer 7, a cathode 8, and a sealing layer 9 are formed successively.

As the electron injection layer 7, for example, a barium thin film may also be formed by vacuum deposition.

As the cathode 8, for example, an ITO thin film may also be formed by sputtering.

An organic EL device is manufactured through the above-described process.

Method for Applying Ink Provided for Formation of Light Emitting Layer using Droplet Ejection Apparatus 100

A method for mass-producing a substrate on which the light emitting layer 6 is formed using the droplet ejection apparatus 100 will be described.

The light emitting layer 6 is formed by applying ink of three colors (ink for a red light emitting layer, ink for a green light emitting layer, and ink for a blue light emitting layer) to regions formed between a plurality of line banks.

Here, for the sake of brevity, the colors are applied one by one in a certain order to a plurality of substrates. Specifically, ink of a first color is first applied to a plurality of substrates. Then, after application of ink of the first color to all the plurality of substrates, ink of a second color is applied to the plurality of substrates. Then, lastly, ink of a third color is applied.

Then, in the following description, a process will be described in which ink of the first color (for example, red ink) is applied to a plurality of substrates, as a representative example.

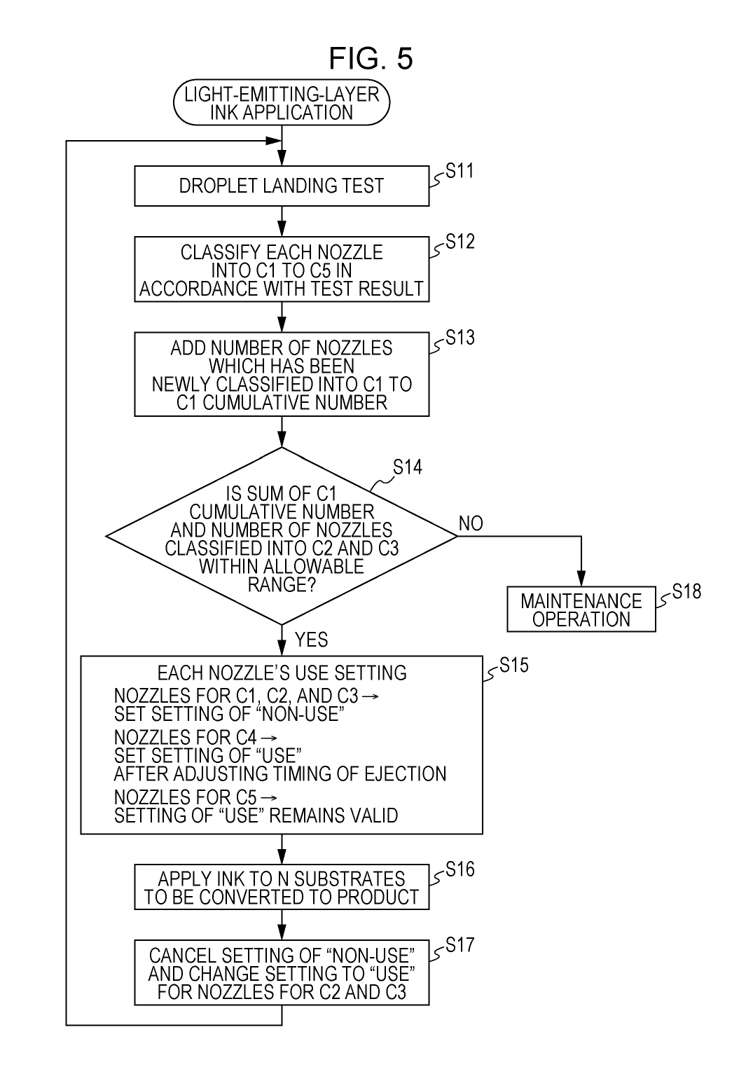

FIG. 5 is a flowchart illustrating a process in which ink provided for a light emitting layer is applied to substrates and coated products are mass-produced. Here, a coated product is a product obtained by arranging a light emitting layer on a substrate to be converted to a product, the light emitting layer being formed of ink provided for the light emitting layer.

This flowchart illustrates a process performed using the droplet ejection apparatus 100 right after performance of a maintenance operation and before performance of the next maintenance operation. Steps S11 to S17 are treated as one cycle, and this cycle is repeated.

In step S11, a droplet landing test is performed for each of the nozzles 125 of the droplet ejection apparatus 100.

Right after performance of a maintenance operation, “use” is set for all the nozzles 125 to be used for application of ink to a substrate to be converted to a product (hereinafter simply referred to as “all the nozzles 125”) among the nozzles provided at the nozzle head 122. Thus, a droplet landing test is performed for all the nozzles 125 right after performance of a maintenance operation.

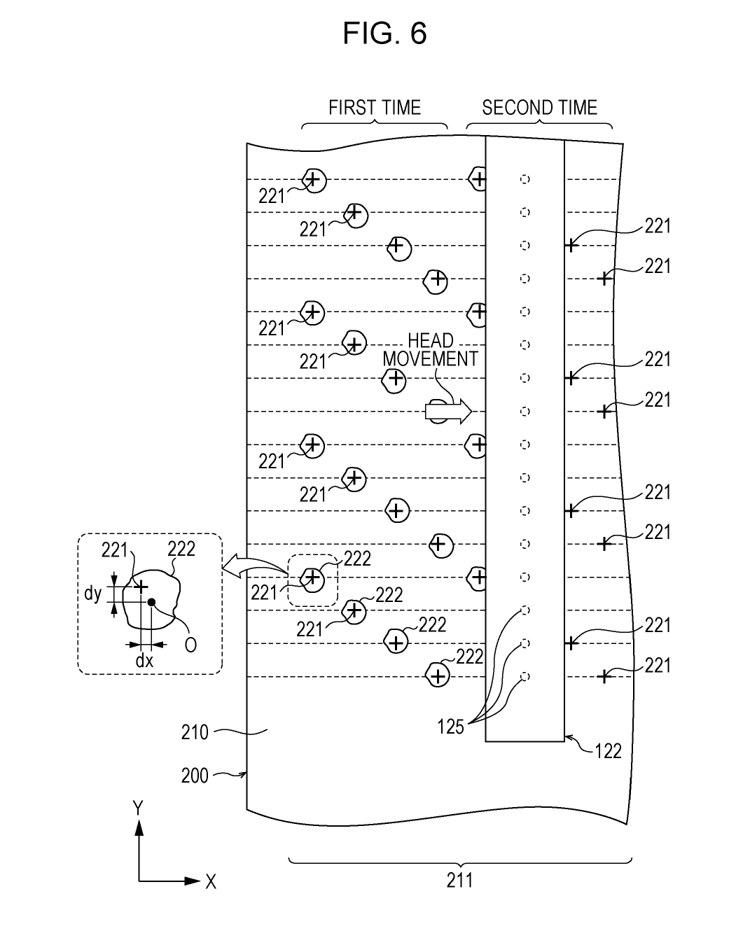

How to perform such a droplet landing test will be described with reference to FIGS. 1 and 6.

The substrate 200, which is a substrate provided for a droplet landing test and is hereinafter referred to as a “substrate 200 provided for a droplet landing test”, is prepared and placed on the base 111 of the droplet ejection apparatus 100 as illustrated in FIG. 1. The substrate 200 provided for a droplet landing test is a liquid repellent substrate. The substrate 200 provided for a droplet landing test may be, for example, a substrate in the middle of production of an organic EL device, and a circumferential area (an edge area) of such a substrate may also be used as a test area 211.

FIG. 6 is a diagram illustrating a method for performing a droplet landing test in the test area 211 of a surface 210 of the substrate 200 provided for a droplet landing test.

As illustrated in FIG. 6, while the nozzle head 122 is being moved in the X direction with respect to the substrate 200 provided for a droplet landing test, ink droplets are ejected from the nozzles 125 taking aim at target positions 221 set in the test area 211.

Ink used here is the same as that used when a light emitting layer is formed on a substrate to be converted to a product.

In the test area 211 of the substrate 200 provided for a droplet landing test and set on the base 111, the target positions 221 are set on a scan line (a broken line in FIG. 6) in the X direction along which the nozzles 125 are moved. The pitch of the nozzles 125 in the Y direction is the same as that of the target positions 221 in the Y direction.

Each of the nozzles 125 has a plurality of target positions 221 set and arranged in the X direction. The number of target positions 221 for each nozzle 125 may be greater than or equal to five, and here suppose ten.

Note that, in an example illustrated in FIG. 6, the target positions 221 of adjacent nozzles 125 are shifted from each other in the X direction. This is to prevent ink droplets, which have been ejected from adjacent nozzles 125 and have landed, from being mixed.

Then, a certain amount of ink is ejected from each nozzle 125 to a plurality of target positions 221 one by one.

FIG. 6 illustrates a state in which ink droplets 222 are scattered in the test area 211 after the first ejection of ink from the nozzles 125. In FIG. 6, next, the second ejection of ink is performed, and furthermore the third to tenth ejection of ink is performed in a successive manner.

After completion of the tenth ejection of ink, a droplet landing deviation of each of the ink droplets 222 adhered to the test area 211 (a positional deviation from a target position) and the area of each ink droplet 222 are measured.

The measurement is performed in the following manner. First, the image capturing device 123 captures an image of the test area 211 to which the ink droplets 222 are adhered. Then, the control device 130 loads data of the image into the memory 132 and measures droplet landing deviations and the area of each ink droplet using image recognition technologies.

Specifically, a two-dimensional image of ink droplets 222 that have landed is captured as illustrated in a partial enlarged view of FIG. 6. Then, the contour of each of the ink droplets 222 when viewed in a planar view is determined and a center position O of the contour is obtained using image recognition technologies from the contrast of the two-dimensional image. Then, the distance between the obtained center position O and a corresponding target position 221 is obtained. In the first embodiment, a distance dx in the X direction between the center position O and the corresponding target position 221 is obtained, and the distance dx in the X direction is treated as a droplet landing deviation. In addition, the area of a region defined by the contour of each ink droplet 222 is calculated and treated as the area of the ink droplet 222. Here, only droplet landing deviations dx in the X direction are used as droplet landing deviations, and droplet landing deviations dy in the Y direction are ignored. This is because the occurrence of droplet landing deviations in the Y direction does not matter since the banks 5 are line banks.

For each of the nozzles 125, droplet landing deviations dx and the area of each droplet obtained in units of ten times of ejection of ink are stored in the memory 132 of the control device 130.

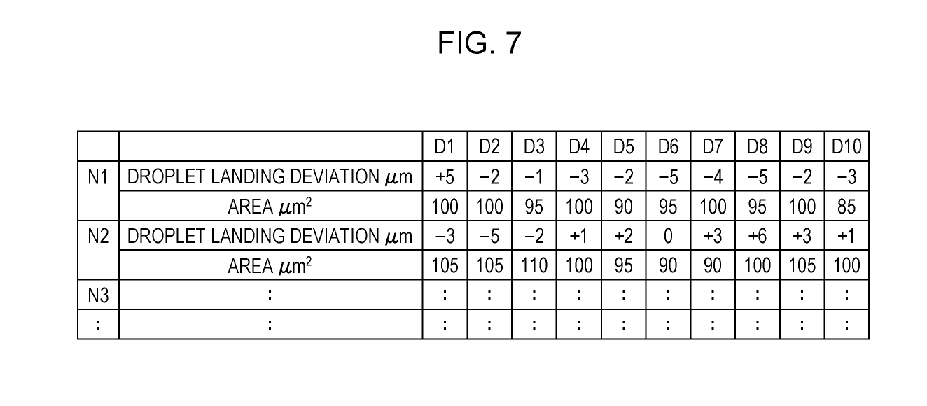

FIG. 7 is a diagram illustrating an example of a data table stored in the memory 132 of the control device 130 as a result of a droplet landing test. All the nozzles 125 are associated with corresponding nozzle numbers N1, N2, N3, and so on. FIG. 7 illustrates, for each nozzle 125, recorded results including measured droplet landing deviations dx of ink droplets D1 to D10 in the X direction and the measured area of each of the ink droplets D1 to D10, the ink droplets D1 to D10 being obtained as a result of performance of droplet landing ten times.

Next, in step S12, for each of the nozzles 125 for which a droplet landing test has been performed, the control device 130 classifies the nozzle 125 into any of C1, C2, C3, C4, and C5 in accordance with a result of the droplet landing test. Then, for each nozzle 125, a result of classification of the nozzle 125 is stored in the memory 132.

A method for classifying the nozzle 125 will be described later in more detail. C1 represents a chronic defective condition level. C2 and C3 represent a temporary defective condition level. C4 and C5 represent a good condition level. (Note that C4 represents a condition in which the timing of ejection needs to be corrected.)

Next, in step S13, the control device 130 adds the number of nozzles 125 which have been newly classified in step S12 into C1 to the cumulative number of nozzles 125 that are chronically defective (hereinafter referred to as a “C1 cumulative number”). The C1 cumulative number has an initial value of 0 right after performance of a maintenance operation and represents the cumulative number of nozzles 125 which have been classified into C1 (the chronic defective condition level) in cycles so far.

In step S14, it is determined whether or not the sum of the C1 cumulative number and the number of nozzles 125 classified in step S12 into the temporary defective condition level (C2 and C3) is within a certain allowable range. When the sum is within the certain allowable range (No in step S14), the process proceeds to step S15. When the sum exceeds the certain allowable range (Yes in step S14), the process proceeds to step S18.

The “allowable range” here is, for example, a range that makes it possible to ensure the amount of ink over the entirety of an ink application area of the substrate 300 to be converted to a product even when only the nozzles 125 classified into the good condition level (C4 and C5) are used.

As the cycle is repeated, when the number of nozzles 125 classified into the good condition level (C4 and C5) decreases, the number of nozzles to be used when ink is applied to the substrate 300 to be converted to a product decreases. In contrast, the amount of ink to be applied to the entirety of the ink application area needs to be retained. To some extent, the amount of ink to be applied may be retained by performing setting such that the amount of ink to be ejected per nozzle to be used is increased. However, when the number of nozzles 125 that are in the good condition becomes too small, it becomes difficult to retain the amount of ink to be applied to the entirety of the ink application area. Thus, as the above-described allowable range, a range has only to be set that is considered to make it possible to perform such an action. The upper limit of such an allowable range is, for example, a number indicating about 8% of the total number of the nozzles 125.

In step S14, when it is determined that the sum of the C1 cumulative number and the number of nozzles 125 classified into the temporary defective condition level exceeds the allowable range, the process proceeds to step S18 and a maintenance operation is performed. That is, when it becomes difficult to ensure the amount of ink to be applied to the entirety of the ink application area, a maintenance operation is performed.

Note that, in the first embodiment, the banks 5 are line banks and the ink ejected to a region between adjacent banks 5 spreads in the Y direction linearly. Thus, in step S14, a determination is made in accordance only with the sum of the C1 cumulative number and the number of nozzles 125 which have been classified into C2 and C3 among all the nozzles 125.

Next, in step S15, as in the following, a setting of “use” or “non-use” are set in accordance with the above-described classification (C1 to C5) for each nozzle 125.

A setting of “non-use” is set for nozzles 125 classified into C1.

A setting of “non-use” is also set for nozzles 125 classified into C2 and C3.

For nozzles 125 classified into C4, the ejection timing is corrected and then “use” is set.

For nozzles 125 classified into C5, the ejection timing is not corrected and “use” is simply set.

Here, when the number of nozzles 125 for which “non-use” is set changes, the amount of ink to be ejected from nozzles 125 to be used is adjusted such that the amount of ink to be ejected from the entirety of the nozzle head 122 becomes constant.

Note that matters related to setting of “use” and “non-use” will be described later in more detail.

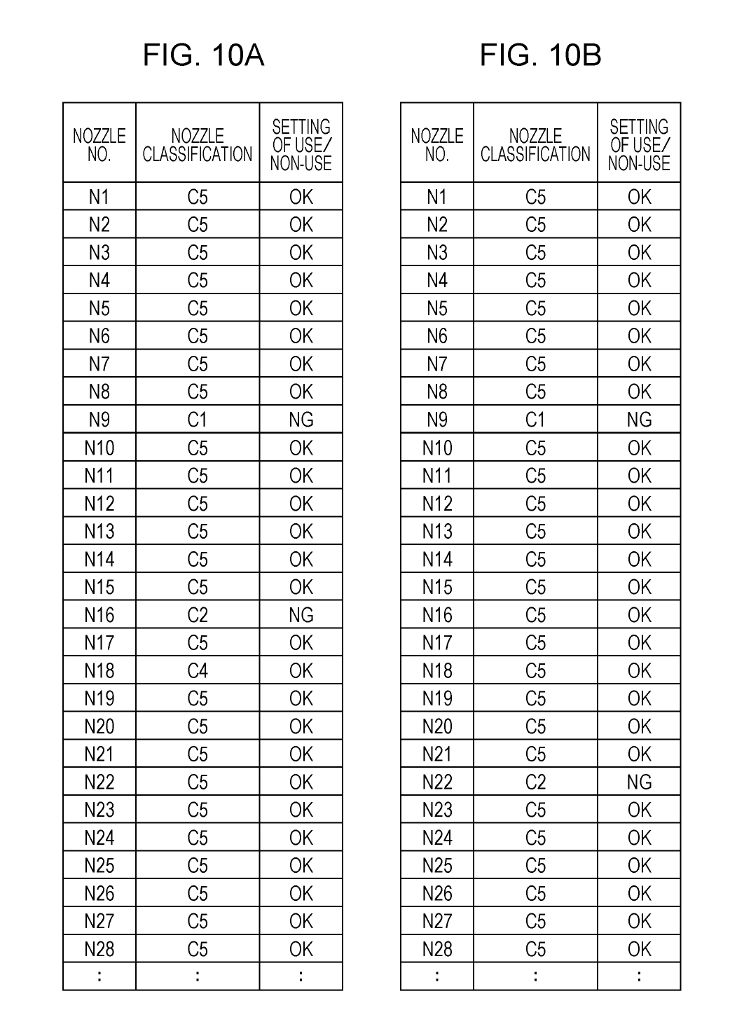

FIGS. 10A and 10B illustrate examples of a management table stored in the memory 132 of the control device 130. This management table illustrates a classification (C1 to C5) and a setting of “use” or “non-use” (OK represents “use” and NG represents “non-use”), for each nozzle number N1, N2, N3, and so on.

Next, in step S16, ink is applied to a certain number (N) of substrates to be converted to products.

This numerical value N denotes the number of substrates each of which is to be converted to a product and to which ink is applied in one cycle. The numerical value is greater than or equal to 1 and, for example, 10 or 20.

A droplet landing test is performed once every time application of ink is completed for N substrates to be converted to a product. The greater the numerical value N is set, the better the production efficiency. However, when the numerical value is too large, while ink is being applied to N substrates, the condition of some nozzles 125 may change to a defective condition and defective products may be manufactured. Thus, the numerical value N is set as appropriate by taking these points into consideration.

A process for applying ink provided for formation of a light emitting layer (ink obtained by dissolving a light emitting material in a solvent) using the droplet ejection apparatus 100 will be described with reference to FIGS. 1 and 11A.

In this process, the substrate 300 to be converted to a product is placed on the work table 110 and ink provided for formation of a light emitting layer is applied.

The substrate 300 is a substrate obtained by forming the anode 2, the ITO layer 3, the hole injection layer 4, and the banks 5 on the substrate 1, as illustrated in FIG. 4A.

As illustrated in FIG. 11A, the substrate 300 is placed on the work table 110 in a state in which the banks 5, which are line banks, extend in the Y direction. An ink droplet is ejected from each nozzle 125 for a droplet landing target set between adjacent line banks while the nozzle head 122, which extends in the Y direction, is being moved in the X direction.

Note that a region where red ink is applied is one of three regions arranged next to each other in the X direction.

In this application process, only the nozzles 125 for which “use” has been set in step S15 are used in accordance with the management table stored in the memory 132. Thus, only the nozzles 125 classified into C4 and C5 in step S12 are used and the nozzles 125 classified into C1, C2, and C3 are not used.

The substrate 300 to be converted to a product is subjected to application of ink and then dried. As a result, a material for a light emitting layer is adhered to the region between adjacent banks 5 on the substrate 300 to be converted to a product and the light emitting layer 6 is formed. In this manner, a coated product is manufactured.

In this manner, ink is applied to N substrates 300 to be converted to a product. Thereafter, in a subsequent step, which is step S17, “use” is set for nozzles 125 classified into the temporary defective condition level (C2 and C3) among the nozzles 125 which have been classified into C1, C2, and C3 and for which “non-use” has been set. In contrast, “non-use” is retained for the nozzles 125 classified into C1.

The operation performed in steps S11 to S17 is treated as one cycle and the cycle is repeated.

In the second and subsequent cycles, the nozzles 125 to be subjected to a droplet landing test in step S21 are the nozzles 125 for which “use” has been set in step S17 of the preceding cycle. Thus, a droplet landing test is performed for the nozzles 125 classified into the temporary defective condition level (C2 and C3) and the nozzles 125 classified into the good condition level (C4 and C5) in step S12 of the preceding cycle. In contrast, a droplet landing test is not performed for the nozzles 125 classified into the chronic defective condition level (C1).

Processing to be performed in steps S12 to S17 of the second and subsequent cycles is the same as that described above, and thus a description thereof will be omitted.

In step S17 while the cycle is being repeated in this manner, when the sum of the C1 cumulative number and the number of nozzles 125 classified into the temporary defective condition level reaches the above-described certain number (Yes in step S14), a maintenance operation is performed for the nozzle head 122 (step S18).

In this manner, according to a mass-production method based on the flowchart of FIG. 5, after performance of the last maintenance operation, the operation from steps S11 to S17 is repeated. While the operation is being repeated, a maintenance operation is not performed. Then, when the number of nozzles 125 that are in the defective condition (the sum of the number of nozzles 125 classified into the temporary defective condition level and the number of nozzles 125 classified into the chronic defective condition level) exceeds a certain allowable range, a maintenance operation is performed.

Methods for performing a maintenance operation for the nozzle head 122 include known methods such as purging, flushing, and wiping.

Specifically, for example, a method for removing clogging compounds by strongly ejecting ink from all the nozzles 125 of the nozzle head 122 may also be used. Alternatively, a method for wiping off ink adhered around an ejection orifice of each nozzle 125 by wiping the surface of the nozzle head 122 may also be used.

### Nozzle Classification Method

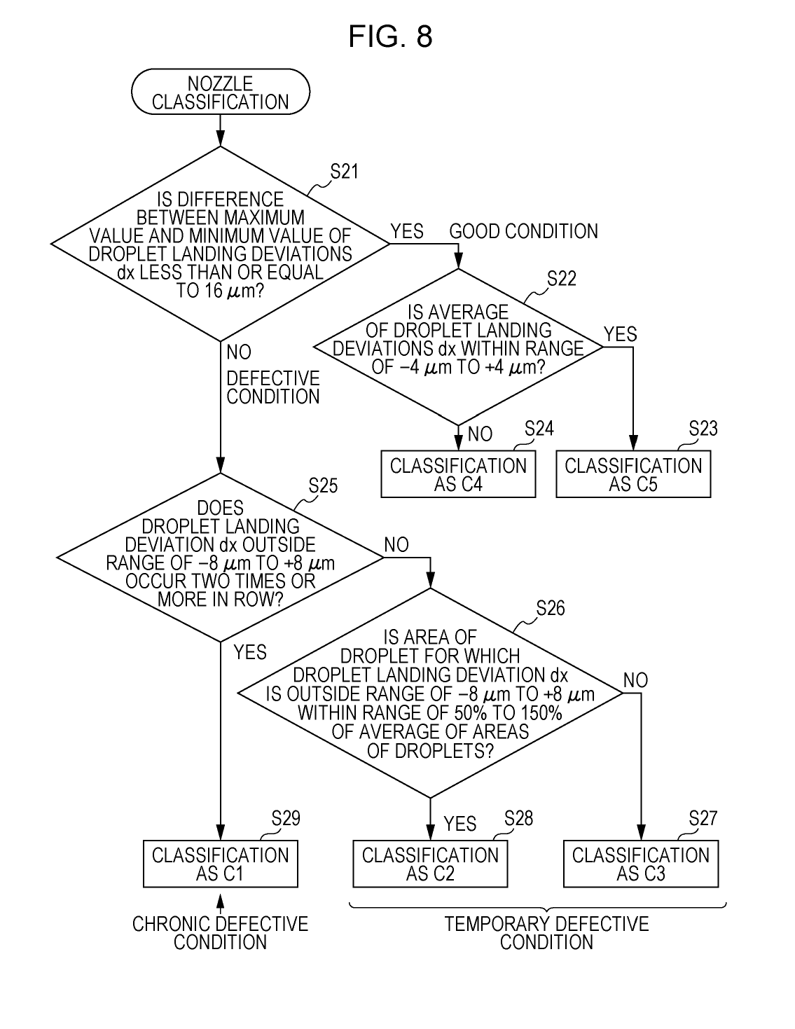

FIG. 8 is a flowchart illustrating a method in which the control device 130 classifies each of the nozzles 125 in accordance with a result of a droplet landing test. A method for classifying the nozzles 125 for which a droplet landing test has been performed, into C1 to C5 in step S12 of FIG. 5 will be described using FIG. 8.

In step S21, it is determined whether or not the dispersion in the droplet landing deviations dx obtained in the measurement performed ten times is within a certain range. Specifically, it is determined whether or not the difference between the maximum value and the minimum value of the droplet landing deviations dx in the X direction measured for droplets (D1 to D10) obtained in the measurement performed ten times is less than or equal to a threshold of 16 μm. When the difference is less than or equal to 16 μm (Yes in S21), the nozzles 125 is determined to be in the good condition and the process proceeds to step S22.

The threshold used here, which is 16 μm, is determined in accordance with the allowable range of droplet landing deviations (the X direction) in the ink application process illustrated in FIG. 11A. Generally, the larger the width of a sub-pixel (the width of a region between line banks) of the substrate 300, which is a coating target, the larger the allowable range of droplet landing deviations (the X direction). Thus, the larger the width of a sub-pixel, the larger value this threshold is set to.

Note that, in the first embodiment, the dispersion is determined in accordance with whether or not the difference between the maximum value and the minimum value of the droplet landing deviations dx obtained in the measurement performed ten times is within a certain range (16 μm or less). However, this is a mere example. For example, a standard deviation of the droplet landing deviations dx obtained in the measurement performed ten times is obtained, and the dispersion may also be determined in accordance with whether or not the value of the standard deviation is within a certain range (for example, 6 μm or less).

In step S22, it is determined whether or not the arithmetic mean value of the droplet landing deviations dx obtained in the measurement performed ten times in the X direction is within a certain range (specifically, within the range of −4 μm to +4 μm). When the arithmetic mean value of the droplet landing deviations dx is within the range of −4 μm to +4 μm, ink droplets land accurately. Thus, it is considered that the nozzle 125 may be used for manufacture as they are in step S16 (Yes in step S22). Then, such a nozzle 125 is classified into C5 (step S23).

In contrast, when the arithmetic mean value of the droplet landing deviations dx is outside the range of −4 μm to +4 μm, it is considered that ink droplets land accurately if the timing of ejection is corrected. Then, such a nozzle 125 is classified into C4.

The range (−4 μm to +4 μm) used for a determination standard in step S22 is set in accordance with, for example, the shortest distance by which the droplet landing position may be adjusted at the timing at which the nozzle 125 ejects an ink droplet.

In step S21, when the difference between the maximum value and the minimum value of the droplet landing deviations dx obtained in the measurement performed ten times exceeds 16 μm (No in step S21), it is considered that the nozzle 125 is either in the temporary defective condition or the chronic defective condition. Then, in subsequent steps S25 and S26, the nozzle 125 is classified into any one of C1 to C3.

In step S25, it is checked whether or not, among the droplet landing deviations dx obtained in the measurement performed ten times, droplet landing deviations having a large absolute value occur solo or successively. Then, as a result, it is determined whether the nozzle 125 is in the temporary defective condition or the chronic defective condition.

Specifically, a droplet landing deviation dx outside the range of −8 μm to +8 μm (that is, the absolute value of a droplet landing deviation dx exceeds 8 μm) does not occur two times or more in a row (No in step S25), it is considered that large droplet landing deviations occur solo and the nozzle 125 is in the temporary defective condition. Then, in that case, the process proceeds to step S26. In contrast, when a droplet landing deviation dx outside the range of −8 μm to +8 μm occurs two times or more in a row (Yes in step S25), it is considered that large droplet landing deviations occur successively and the nozzle 125 is in the chronic defective condition. Then, in such a case, the nozzle 125 is classified into C1 (step S29).

Note that, here, the range of the standard (−8 μm to +8 μm) used to determine whether or not large droplet landing deviations occur solo is 16 μm, the standard is caused to match the threshold used in step S21, which is 16 μm. However, these values do not have to match.

In step S26, the nozzle 125 determined to be in the temporary defective condition is further classified into C3 or C2 in accordance with whether or not a large droplet landing deviation, which has occurred solo, has a large change in the area of a droplet.

When the large droplet landing deviation, which has occurred solo, has a large change in the area of a droplet, it is considered that there is a high probability that the large droplet landing deviation has been caused by dirt or foreign materials on a substrate provided for a droplet landing test. Thus, in this case, it is considered that if the droplet landing test is performed again, there is a high probability that the nozzle 125 returns to be in the good condition, and the nozzle 125 is classified into C3. In contrast, when the large droplet landing deviation, which has occurred solo, does not have a large change in the area of a droplet, the nozzle 125 is classified into C2.

As a specific example, when the area of a droplet, landing deviation dx of which is outside the range of −8 μm to +8 μm, is greater than 150% or smaller than 50% of the arithmetic mean value of areas of droplets obtained in the measurement performed ten times (No in step S26), the nozzle 125 is classified into C3 (step S27). In contrast, when all the areas of droplets, landing deviation dx of which is outside the range of −8 μm to +8 μm, are within 50% to 150% of the arithmetic mean value of the areas of droplets (Yes in step S26), the nozzle 125 is classified into C2 (step S28).

As described above, each of the nozzles 125 for which a droplet landing test has been performed is classified into any one of C1 to C5.

Here, as an example, the above-described classification method will be specifically described using measurement results of a nozzle N1 illustrated in FIG. 7.

First, in the measurement results of the nozzle N1, the maximum value of the droplet landing deviations dx is 5 μm (a droplet D1) and the minimum value of the droplet landing deviations dx is −5 μm (droplets D6 and D8). Thus, the difference between the maximum value and the minimum value is 10 μm. Since this value is less than or equal to 16 μm, Yes is obtained in step S21 (it is determined that the nozzle N1 is in the good condition).

Next, the arithmetic mean value of the droplet landing deviations dx in the measurement results of the nozzle N1 is

(5−2−1−3−2−5−4−5−2−3)÷10=−2.2 (μm).

Since this value is within the range of −4 μm to +4 μm, Yes is obtained in step S22.

Thus, the nozzle N1 illustrated in FIG. 7 is classified into C5.

Specific Example of Classification of Nozzle in Accordance with Result of Droplet Landing Test and Setting of Use or Non-Use

As described above, each of the nozzles 125 is classified into any one of C1 to C5. In step S15, for each of the nozzles 125, “use” or “non-use” is set in accordance with the classification results.

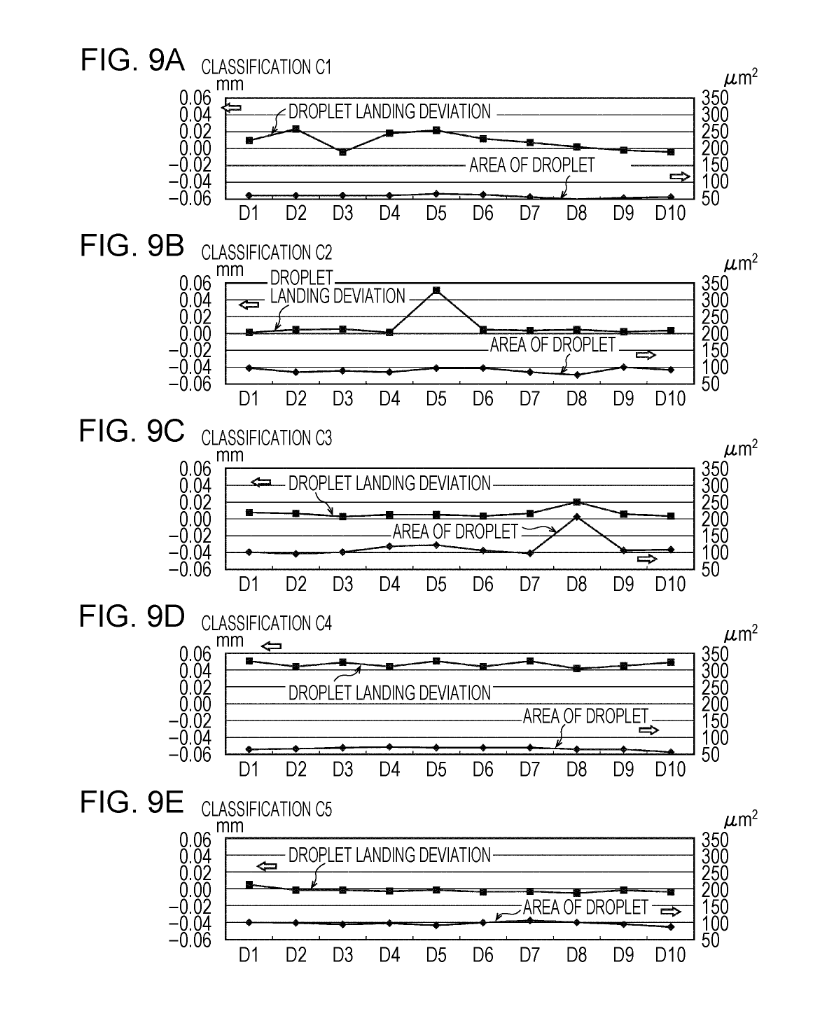

FIGS. 9A to 9E illustrate a specific example of a result of a droplet landing test performed for the nozzles 125. These diagrams illustrate, for droplets D1 to D10 obtained as a result of ten times of droplet landing, droplet landing deviations dx in the X direction (μm) and the area of each droplet (μm²).

In addition, these diagrams illustrate representative measurement results classified into each of C1 to C5.

In the case where results of a droplet landing test are as in FIGS. 9A to 9E, as in the following, the nozzles 125 are classified into C1 to C5 and “use” or “non-use” is set in step S15.

In the measurement results illustrated in FIG. 9A, the difference between the maximum value and the minimum value of the droplet landing deviations dx obtained in the measurement performed ten times is greater than 16 μm. In addition, droplet landing deviations dx having a size greater than or equal to 8 μm have occurred two times or more in a row. Thus, the nozzle 125 whose measurement results are illustrated in FIG. 9A is determined to be in the chronic defective condition and the nozzle 125 is classified into C1.

It is considered that, for example, dirt adhered near the ejection orifice of the nozzle 125 or a bubble present in the ejection orifice of the nozzle 125 causes chronic droplet landing deviations.

A setting of “non-use” is set in step S15 for nozzles 125 classified into C1, and the nozzles 125 are not subjected to a droplet landing test in the next cycle. Thus, the nozzles 125 classified into C1 are retained in a non-use state.

The measurement results illustrated in FIG. 9B include a droplet landing deviation dx that is outside the range of −8 μm to +8 μm. However, such a large droplet landing deviation dx occurs solo, and the droplet landing deviations dx immediately before and after the large droplet landing deviation dx are within the range of −8 μm to +8 μm. In addition, the area of the droplet having such a large droplet landing deviation dx is within the range of 50% to 150% of the arithmetic mean value area. Thus, the nozzle 125 whose measurement results are illustrated in FIG. 9B, is classified into C2.

Such a solo droplet landing deviation is not reproducible and it is difficult to determine causes of a solo droplet landing deviation. However, for example, a very small amount of ink ejected last time and adhered near the nozzle 125 is considered as a cause, the adhered ink pulling ink to be ejected from the nozzle 125 and changing the direction of the ink.

A setting of “non-use” is set in step S15 for nozzles 125 classified into C2. Thus, the nozzles 125 classified into C2 are not used when ink is applied in step S16 to a substrate to be converted to a product. However, the setting is changed to “use” in step S17, and a droplet landing test is performed in step S11 of the next cycle. The nozzles 125 which have been classified into C2 may be changed to the good condition.

Thus, the nozzles 125 classified into C2 may be used for application of ink to a substrate to be converted to a product in step S16 of the next cycle.

The measurement results illustrated in FIG. 9C also include a droplet landing deviation dx that is outside the range of −8 μm to +8 μm and that occurs solo; however, large droplet landing deviations dx do not occur immediately before and after such a droplet landing deviation dx. However, the area of the droplet having a large droplet landing deviation dx is outside the range of 50% to 150% of the arithmetic mean value area. FIG. 9C differs from FIG. 9B in terms of this point, and the nozzle 125 whose measurement results are illustrated in FIG. 9C is classified into C3.

A setting of “non-use” is set in step S15 for nozzles 125 classified into C3. Thus, the nozzles 125 classified into C3 are not used when ink is applied to a substrate to be converted to a product. However, the setting is changed to “use” in step S17. It is considered that the nozzles 125 classified into C3 are more likely to be in the good condition in the next cycle than the nozzles 125 classified into C2. That is, it is considered that the nozzles 125 classified into C3 are more likely to be used in application of ink to a substrate to be converted to a product in step S16 than the nozzles 125 classified into C2.

In the measurement results illustrated in FIG. 9D, the difference between the maximum value and the minimum value of the droplet landing deviations dx obtained in the measurement performed ten times is less than or equal to 16 μm. However, since the arithmetic mean value of the droplet landing deviations dx is outside the range of −4 μm to +4 μm, the condition of the nozzle 125 is classified into C4.

Since the dispersion in the droplet landing deviations dx is small, the nozzles 125 classified into C4 are in good condition; however, the arithmetic mean value of the droplet landing deviations dx is relatively large. Thus, it is considered that droplets may land stably near target positions if the ejection timing is adjusted. Thus, in step S15, after adjustment of the ejection timing, “use” is set for the nozzles 125 classified into C4.

In the measurement results illustrated in FIG. 9E, the difference between the maximum value and the minimum value of the droplet landing deviations dx obtained in the measurement performed ten times is less than or equal to 16 μm and the arithmetic mean value of the droplet landing deviations dx is also within the range of −4 μm to +4 μm. Thus, the nozzle 125 whose measurement results are illustrated in FIG. 9E is classified into C5.

The nozzles 125 classified into C5 cause droplets to land stably near target positions. Thus, in step S15, “use” is set for the nozzles 125 classified into C5, without correcting the ejection timing.

Note that, in graphs illustrated in FIGS. 9A to 9E, the areas of droplets differ greatly between graphs. Before an image of a droplet is captured after ink is ejected, the ink is dried and the area of the droplet changes. In addition, the speed at which a droplet dries depends on an ink ejection position. As a result, the areas of droplets for FIGS. 9A to 9E differ greatly between graphs. Thus, it is considered that the area of a droplet is not relevant to the droplet landing accuracy very much. Thus, not the area of a droplet but a percentage relative to the arithmetic mean value of areas of droplets is used for evaluation of the droplet landing accuracy.

Steps S11 to S17 are treated as one cycle, and this cycle is repeated. How repetition of this cycle changes classification of the nozzles 125 and setting of “use” or “non-use” will be described through an example.

FIGS. 10A and 10B illustrate an example of a management table with which the control device 130 is provided, and illustrate classification set in steps S12 and S15 for each of the nozzles N1, N2, and the like and “use” or “non-use” set in accordance with the classification.

In the management table illustrated in FIG. 10A, the nozzle denoted by N9 is classified into C1 and “non-use” is set. The nozzle denoted by N16 is classified into C2 and “non-use” is set. The nozzle denoted by N18 is classified into C4 and “use” is set.

The management table illustrated in FIG. 10B illustrates classification set in steps S12 and S15 in the next cycle for each of the nozzles N1, N2, and the like and “use” or “non-use” set in accordance with the classification.

In FIG. 10A, the nozzle N9 has been classified into C1, which is the chronic defective condition, and “non-use” is set. Thus, even in FIG. 10B, the nozzle N9 is still classified into C1 and “non-use” is set.

In contrast, the nozzle N16, which has been classified into C2 in FIG. 10A, is classified into C5 in FIG. 10B and “use” is set. In this manner, the condition of a nozzle classified into the temporary defective condition level may change to the good condition and the nozzle may be used for manufacturing a product in the next cycle.

In addition, the nozzle denoted by N22 has been classified into C5 and “use” has been set in FIG. 10A. However, in FIG. 10B, the nozzle N22 is classified into C2 and “non-use” is set. In this manner, the condition of a nozzle classified into the good condition level may change to the defective condition and the nozzle may no longer be used for manufacturing a product in the next cycle.

### Benefit of Ink Application Method of First Embodiment

According to the above-described ink application method, in one cycle, the nozzles 125 classified into C4 and C5 are selected, C4 and C5 being the good condition level, in accordance with a result of a droplet landing test (S11), and ink is applied to a substrate to be converted to a product (step S16). Thus, the droplet landing accuracy is ensured.

While a series of operations (S11 to S17) is being repeatedly performed, there may be the case where the condition of nozzles 125 classified into the good condition level changes to the defective condition during a process in which ink is applied to a substrate to be converted to a product. However, even in such a case, in the next cycle, the nozzles 125 the condition of which has changed to the defective condition are subjected to a droplet landing test (S11), each of the nozzles 125 is classified into C1 or C2 (S12), and “non-use” is set (S15). Thus, it does not happen that the nozzles 125 the condition of which has changed to the defective condition are continuously used. For example, the nozzle N22 of FIGS. 10A and 10B corresponds to such a case. That is, the nozzle N22 classified into C5 is classified into C2 and “non-use” is set in the next cycle.

In this manner, according to the above-described ink application method of the first embodiment, while the series of operations (S11 to S17) is being repeatedly performed, the occurrence of landing-of-droplet defectiveness may be reduced without performing a maintenance operation.

Thus, even when a maintenance interval is increased, the droplet landing accuracy may be ensured.

In addition, when the sum of the C1 cumulative number and the number of nozzles 125 classified into C2 and C3 is within a certain allowable range, a maintenance operation is not performed. Then, when the sum reaches the upper limit of the allowable range, a maintenance operation is performed. That is, only after the time when, after performance of the last maintenance operation, the number of nozzles 125 considered to be in the good condition decreases and it becomes difficult to ensure the amount of ink to be applied, a maintenance operation is performed. Thus, the period of maintenance is more appropriately set than in the case where a maintenance operation is periodically performed.

Furthermore, according to the above-described ink application method, a nozzle 125 classified into the temporary defective condition level may be classified into the good condition level again and used for manufacturing a product during the repetition of the cycle. Thus, an increase in the cumulative number of nozzles 125 classified into the defective condition level may be reduced by the number of nozzles 125 which is classified into the good condition level again.

That is, since there is a low probability that the condition of nozzles 125 that have been once classified into C1 changes to the good condition even when a droplet landing test is performed again, the nozzles 125 classified into C1 are not subjected to a droplet landing test in the next cycle. In contrast, the setting of “non-use” is changed to “use” in step S17 for the nozzles 125 classified into C2 and C3, C2 and C3 being the temporary defective condition level, and the nozzles 125 classified into C2 and C3 are subjected to a droplet landing test in the next cycle. Thus, as a result of a droplet landing test, there may be the case where the condition of nozzles 125 changes to the good condition. For example, in an example of FIG. 10, the nozzle N16 corresponds to such a case. The nozzle N16 classified into C2 is classified into C5 and “use” is set in the next cycle.

In contrast, as a comparison example, the case is considered in which processing in step S17 (processing for canceling a setting of “non-use” for C2 and C3) is omitted in the flowchart of FIG. 5. In this case, the nozzles 125 classified into the temporary defective condition level and for which “non-use” has been set are not subjected to a droplet landing test in the next cycle. Thus, for such nozzles, “non-use” is retained and the setting is not changed to “use” in the next cycle. When compared with such a comparison example, according to the first embodiment, an increase in the cumulative number of nozzles 125 classified into the defective condition level may be reduced by the number of nozzles 125 that return to be in the good condition and are used, the nozzles 125 having been classified into the temporary defective condition level. Thus, the maintenance interval may be increased.

Note that a certain landing accuracy may not be achieved when the nozzles 125 classified into the temporary defective condition level (C2 and C3) are used as they are, to apply ink to a substrate to be converted to a product. However, in the first embodiment, the nozzles 125 classified into the temporary defective condition level (C2 and C3) in a certain cycle are not used to apply ink to a substrate to be converted to a product in step S16 of the certain cycle. Only in the case where, in the next cycle, the nozzles 125 are subjected to a droplet landing test and determined to be in the good condition, the nozzles 125 are used for manufacturing products.

According to the first embodiment, the droplet landing accuracy may be ensured in the case where ink is applied to a substrate to be converted to a product also in terms of this point.

### Second Embodiment

The form of a bank is a line bank in the first embodiment. In a second embodiment, as illustrated in FIG. 11B, a pixel bank having a grid shape is formed on the substrate 300 to be converted to a product. Sub-pixels having a rectangular shape are defined by this pixel bank.

A method for mass-producing coated products by applying ink to the substrate 300 is basically the same as that described in the first embodiment in accordance with the flowchart of FIG. 5. In the following, points different from those described in the first embodiment will be mainly described.

In the process for applying ink to a substrate to be converted to a product (step S16), the substrate 300 to be converted to a product is placed on the work table 110 of the droplet ejection apparatus 100, the substrate 300 having a grid-shaped pixel bank, and ink is applied to regions, which are sub-pixels defined by the pixel bank.

Here, the substrate 300 is placed such that the longitudinal direction of each sub-pixel is the Y direction and the direction of the width of each sub-pixel is the X direction. The nozzle head 122 is moved in the X direction, and ink is ejected from each nozzle 125 toward a droplet landing target of the nozzle 125. FIG. 11B illustrates target positions in a red sub-pixel region in the case where red ink is applied.

Note that, as illustrated in FIG. 11B, only nozzles 125 that pass over sub-pixel regions are used among the nozzles 125 of the nozzle head 122. The nozzles 125 that do not pass over the sub-pixel regions, that is, the nozzles 125 marked with x in FIG. 11B are not used at all. In terms of this point, the second embodiment differs from the first embodiment. In an example illustrated in FIG. 11B, seven target positions are set for one sub-pixel region in the Y direction and ink is ejected from seven nozzles 125.

In addition, since the banks in the first embodiment are line banks, the occurrence of a droplet landing deviation in the Y direction does not matter. However, in the case of a pixel bank, the occurrence of a droplet landing deviation in the Y direction also matters. Thus, in the second embodiment, in the droplet landing test in step S11, landing deviations of droplets are measured not only in the X direction (dx) but also in the Y direction (dy).

Then, for classification of the nozzles 125 (step S12), it is determined whether or not conditions are satisfied not only for droplet landing deviations dx in the X direction but also for droplet landing deviations dy in the Y direction, and the nozzles 125 are classified. Specifically, in step S21 of FIG. 8, the conditions are that the difference between the maximum value and the minimum value of droplet landing deviations dx in the X direction is less than or equal to 16 μm and that the droplet landing deviations dy in the Y direction are within a certain range (for example, −10 μm to +10 μm). In the case where these conditions are satisfied, that is, in the case where Yes is obtained in step S21, a certain nozzle 125 among the nozzles 125 is determined to be in the good condition and the process proceeds to step S22. In the case where these conditions are not satisfied, that is, in the case where No is obtained in step S21, a certain nozzle 125 among the nozzles 125 is determined to be in the defective condition and the process proceeds to step S25.

Note that, the above-described range (−10 μm to +10 μm) used as a determination standard for droplet landing deviations dy in the Y direction are values determined in accordance with an allowable range of droplet landing deviations illustrated in FIG. 11B (in the Y direction).

In addition, since line banks are used in the first embodiment, it is determined in step S14 whether or not the sum of the C1 cumulative number and the number of nozzles 125 classified into C2 and C3 among all the nozzles 125 is within a certain allowable range. However, the bank of the second embodiment is a pixel bank and ink to be ejected to each sub-pixel region does not flow into other adjacent sub-pixel regions arranged in the Y direction. Thus, the determination standard used in step S14 is also different.

That is, in the second embodiment, in step S14, a determination is made for each sub-pixel region in accordance with whether or not the sum of the C1 cumulative number and the number of nozzles 125 classified into C2 and C3 is within a certain allowable range. For example, for all the sub-pixel regions, when the sum of the C1 cumulative number and the number of nozzles 125 classified into C2 and C3 is less than or equal to one among seven nozzles 125 corresponding to respective sub-pixels, the process proceeds to step S15 and ink is applied to a substrate to be converted to a product. In contrast, when there is even one sub-pixel region for which the sum of the C1 cumulative number and the number of nozzles 125 classified into C2 and C3 is greater than or equal to two, the process proceeds to step S18 and a maintenance operation is performed.

Although there are differences as described above, benefits similar to those described in the first embodiment may be obtained even in the second embodiment.

### MODIFIED EXAMPLE

### Modified Example 1

In the above-described first and second embodiments, “non-use” is set in step S15 for all the nozzles 125 classified into the temporary defective condition level (the nozzles 125 classified into C2 and C3). Thereafter, the setting of “non-use” is canceled and changed to “use” in step S17. However, it is considered that the nozzles 125 classified into C3 are more likely to return to be in the good condition than the nozzles 125 classified into C2. Thus, in step S17, the setting of “non-use” may be canceled and changed to “use” only for the nozzles 125 classified into C3.

In this case, in the next cycle, some of the nozzles 125 classified into the temporary defective condition level (the nozzles 125 classified into C3) and the nozzles 125 classified into the good condition level (the nozzles 125 classified into C4 and C5) are subjected to a droplet landing test in the next cycle. Thus, chances to be subjected to a test again and to be used again for manufacturing products are not given to the nozzles 125 classified into C2. However, chances to be subjected to a test again and to be used again are still given to the nozzles 125 classified into C3. Thus, an increase in the cumulative number of nozzles 125 classified into the defective condition level may be reduced by the number of nozzles 125 classified into the good condition level again.

### Modified Example 2

In the above-described first and second embodiments, the nozzles 125 determined to be in the temporary defective condition are classified into C2 and C3 in accordance with the amount of a change in the area of a droplet that has landed. However, classification may also be performed in consideration of results obtained through a plurality of times of a droplet landing test in the cycles performed in the past. For example, for a certain nozzle 125, a rank, which indicates a probability of returning to be in the good condition, may be assigned in accordance with the number of times at which the nozzle 125 has been classified into the temporary defective condition level, and the nozzle 125 may be classified in accordance with this rank.

For example, when the number of times at which a nozzle 125 has been classified into the temporary defective condition level in the past is small, it is assumed that the nozzle 125 is highly likely to return to be in the good condition when subjected to a droplet landing test again. Thus, in step S12, the nozzles 125 classified into the temporary defective condition level are classified into nozzles classified into the temporary defective condition level less times in the past and those classified into the temporary defective condition level more times in the past. Then, in step S17, the setting of “non-use” may also be canceled and changed to “use” again for the nozzles 125 classified into the temporary defective condition level less times in the past and nozzles 125 classified into good condition level.

### Modified Example 3

In the above-described first and second embodiments, the nozzles 125, which have been determined to be in the temporary defective condition, are furthermore classified into two condition levels C2 and C3 in accordance with the probability of returning to be in the good condition. However, such nozzles 125 determined to be in the temporary defective condition may also be classified into three condition levels or more in accordance with the probability of returning to be in the good condition.

In such a case, in step S17, many variations may be considered as to which of the condition levels are subjected to cancellation of “non-use” and changing of the setting to “use” again. For example, only one condition level closest to the good condition level may be subjected to cancellation of “non-use”, or the condition level closest to and the condition level second closest to the good condition level may also be subjected to cancellation of “non-use”.

### Modified Example 4

In the above-described first and second embodiments, a description has been made in which ink of one of three colors (red, green, and blue) is applied to a plurality of substrates 300 using the droplet ejection apparatus 100 having one nozzle head, and then ink of another one of the three colors is applied to the substrates 300 on which the ink of the one of the three colors has been applied. However, the above-described ink application method may also be used even in the case where three nozzle heads for red, for green, and for blue are provided in the droplet ejection apparatus 100 and ink of three colors is applied to the substrates 300 in a parallel manner.

For example, a series of processes from steps S11 to S17 is repeated using three nozzle heads for three colors in a parallel manner and ink of the three colors is applied to a substrate in a parallel manner. In step S14, for any of the three nozzle heads for the three colors, when the sum of the C1 cumulative number and the number of nozzles classified into C2 and C3 exceeds a certain allowable range, a maintenance operation in step S18 is performed.

As a result, benefits similar to those described in the first and second embodiments may be obtained.

### Modified Example 5

In the above-described first and second embodiments, an example has been described in which the above-described ink application method is applied to a process for forming a light emitting layer of an organic EL device. However, the above-described ink application method may not only be applied to this example but also be widely applied to the case where coated products are mass-produced, which is a substrate on which a layer formed of ink is arranged, the layer being arranged by applying droplets such as ink on the substrate, and benefits similar to those described in the first and second embodiments may be obtained.

For example, the above-described ink application method may also be applied to the case where functional layers other than a light emitting layer in an organic EL device, for example, a hole injection layer, a hole transport layer, an electron transport layer, and an electron injection layer are formed by a wet method. In addition, the above-described ink application method may also be applied to the case where an organic semiconductor layer on a TFT substrate is formed by a wet method.

A method for mass-producing coated products according to an aspect of the present disclosure may be widely used, for example, for manufacturing a passive-matrix organic EL device and an active-matrix organic EL device and manufacture of a device such as a TFT substrate.

What is claimed is:

1. A method for mass-producing coated products having substrates comprising:
(a) selecting one or more nozzles from among the plurality of nozzles;
(b) testing droplet landing accuracies of the one or more nozzles selected in the selecting (a) by causing a droplet to be ejected from the one or more nozzles;
(c) classifying each of the one or more nozzles into one of a chronic defective condition level, a temporary defective condition level, and a good condition level in accordance with the droplet landing accuracies obtained in the testing (b); and
(d) ejecting droplets toward at least one of the substrates with nozzles classified into the good condition level in the classifying (c), without using nozzles classified into the chronic defective condition level and the temporary defective condition level in the classifying (c), such that layers formed of the droplets are arranged on the substrates, wherein
the selecting (a), the testing (b), the classifying (c), and the ejecting (d) are repeatedly performed in this order as a cycle, and
in the selecting (a), nozzles classified into the good condition level in the classifying (c) of a preceding cycle and at least one of nozzles classified into the temporary defective condition level in the classifying (c) of the preceding cycle are selected.

2. The method for mass-producing coated products according to claim 1, wherein in a case where a sum of a cumulative number of nozzles classified into the chronic defective condition level and a number of nozzles classified into the temporary defective condition level exceeds a certain value, a maintenance operation is performed for at least one of the plurality of nozzles.

3. The method for mass-producing coated products according to claim 1, wherein
in the testing (b), deviations of landing position where droplets actually land from target positions where droplets aim for are measured about each of the one or more nozzles by causing a droplet to be ejected from each of the one or more nozzles a plurality of times, and
in the classifying (c), each of the one or more nozzles is classified into one of the chronic defective condition level, the temporary defective condition level, and the good condition level in accordance with the deviations.

4. The method for mass-producing coated products according to claim 3, wherein, in the classifying (c),
a nozzle the deviations of which have a dispersion greater than a first reference value is classified into one of the chronic defective condition level and the temporary defective condition level, and
a nozzle the deviations of which have a dispersion less than or equal to the first reference value is classified into the good condition level.

5. The method for mass-producing coated products according to claim 4, wherein, among nozzles classified into one of the chronic defective condition level and the temporary defective condition level in classifying (c),
a nozzle the deviations of which include two consecutive deviations greater than or equal to a second reference value is classified into the chronic defective condition level, and
a nozzle the deviations of which do not include two consecutive deviations greater than or equal to the second reference value is classified into the temporary defective condition level.

6. The method for mass-producing coated products according to claim 1, wherein among nozzles classified into the good condition level in the classifying (c), an ejection condition of a nozzle the deviations of which have an arithmetic mean value greater than a third reference value is corrected before the ejecting (d).

7. The method for mass-producing coated products according to claim 1, wherein
in the classifying (c), a nozzle classified into the temporary defective condition level is classified into one of a first temporary defective condition level and a second temporary defective condition level, a nozzle classified in the second temporary defective condition level being less likely to be classified in the good condition level in a later cycle than a nozzle classified in the first temporary defective condition level, and
in the selecting (a), a nozzle classified into the first temporary defective condition level in the classifying (c) of the preceding cycle and a nozzle classified into the good condition level in the classifying (c) of the preceding cycle are selected.
